(19) United States
(12) Patent Application Publication
(10) Pub. No.: US 2023/0314609 A1
(43) Pub. Date: Oct. 5, 2023

(54) PROXIMITY SENSING

(71) Applicant: ams International AG, JONA (CH)

(72) Inventors: Vijay ELE, Hyderabad (IN); Sandeep VERNEKAR, Hyderabad (IN); Dinesh KURUGANTI, Guntur, Andhra Pradesh (IN)

(73) Assignee: ams International AG, JONA (CH)

(21) Appl. No.: 18/044,116

(22) PCT Filed: Sep. 6, 2021
(86) PCT No.: PCT/EP2021/074516

§ 371 Date: Mar. 6, 2023

(30) Foreign Application Priority Data
Sep. 7, 2020 (GB) 2014042.2

(51) Int. Cl. G01S 17/10; H03K 17/94

(52) U.S. Cl. CPC G01S 17/10; H03K 17/941; H03K 2217/94108

(57) ABSTRACT

A method of proximity sensing which comprises emitting light from an emitter and detecting reflected light, applying an offset to the detected reflected light to provide an output signal indicative of proximity, determining an average signal of the output signal; determining whether drift has occurred by comparing the output signal to a first threshold and comparing the average signal to a different threshold, and adjusting the offset if drift is identified.

### CROSS-REFERENCE TO RELATED APPLICATIONS

This patent application is the national stage entry of International Patent Application No. PCT/EP2021/074516, filed on Sep. 6, 2021, and published as WO 2022/049291 A1 on Mar. 10, 2022, and claims priority to Great Britain patent application 2014042.2 filed on Sep. 7, 2020, the disclosures of all of which are hereby incorporated by reference in their entireties.

### TECHNICAL FIELD OF THE DISCLOSURE

The disclosure relates to a method of proximity sensing, and to a proximity sensing system.

### BACKGROUND OF THE DISCLOSURE

The present disclosure relates to a method of proximity sensing. Proximity sensing is used to determine when a smartphone is close to an object. The object may for example be a user's ear, or may be fabric of a user's pocket. When a proximity sensor determines that a smartphone is close to an object then the display screen of the smartphone is turned off and touch-sensitivity of the display screen is disabled. This advantageously prolongs battery life and ensures that operations of the phone are not accidentally initiated. When a proximity sensor determines that the smartphone has moved away from the object then the display screen is switched on and touch-sensitivity is enabled.

This allows a user to see images on the display screen and to operate the smartphone.

A problem which may occur with proximity sensing is that the proximity sensor may wrongly determine that a smartphone is close to an object when it is not, or may fail to identify that a smartphone has been moved away from an object.

It is therefore an aim of the present disclosure to provide proximity sensing that addresses one or more of the problems above or at least provides a useful alternative.

### SUMMARY

In general, this disclosure proposes to overcome the above problems by applying an offset to a signal output from a proximity sensor, the offset being adjusted for drift which is identified by comparing the output signal to a first threshold and comparing an average signal (e.g. a rolling average signal) to a different threshold.

According to a first aspect of the present disclosure, there is provided a method of proximity sensing comprising emitting light from an emitter and detecting reflected light, applying an offset to the detected reflected light to provide an output signal indicative of proximity, determining an average signal of the output signal, determining whether drift has occurred by comparing the output signal to a first threshold and comparing the average signal to a different threshold, and adjusting the offset if drift is identified.

Determining drift in this way advantageously allows drift to be identified whilst at the same time avoiding movement of the system towards or away from an object being incorrectly identified as drift.

Preferably, drift is not identified until the output signal and the average signal satisfy the threshold criteria for drift for a predetermined period of time.

The period of time may be 300 μs or more, may be 700 μs or more, or may be 1.5 ms or more. The period of time may be a value up to 26 ms, a value up to 13 ms, or may be a value up to 6 ms.

The predetermined period of time may be a predetermined number of proximity measurement cycles.

The predetermined number of proximity measurement cycles may be 3 or more, may be 7 or more, may be 10 or more, or may be 15 or more. The predetermined number of proximity measurement cycles may be a value up to 256, a value up to 128, or may be a value up to 64.

Drift may be identified if the average signal is between a first upper boundary threshold and a second upper boundary threshold, and the output signal is below the second upper boundary threshold.

Drift may be identified if the output signal is greater than a release threshold and the average signal is less than a pick-up threshold.

Drift may be identified if the average signal is greater than a third upper boundary threshold and the output signal is less than a fourth upper boundary threshold.

Drift may also be also identified if the average signal falls below a lower boundary threshold.

A measurement of the time may be reset when the offset is adjusted.

According to a second aspect of the invention there is provided a proximity sensing system comprising an emitter configured to emit light, a detection system configured to detect reflected emitted light and provide an output signal indicative of proximity, and an offset determining system configured to determine an average signal of the output signal, determine whether drift has occurred by comparing the output signal to a first threshold and comparing the average signal to a different threshold, and adjust the offset if drift of the offset is identified.

The proximity sensing system advantageously allows drift to be identified whilst at the same time avoiding movement of the system towards or away from an object being incorrectly identified as drift.

The offset determining system may be configured not to identify drift until the output signal and the average signal have satisfied the threshold criteria for drift for a predetermined period of time.

The period of time may be 300 μs or more, may be 700 μs or more, or may be 1.5 ms or more. The period of time may be a value up to 26 ms, a value up to 13 ms, or may be a value up to 6 ms.

The predetermined period of time may be a predetermined number of proximity measurement cycles.

The predetermined number of proximity measurement cycles may be 3 or more, may be 7 or more, may be 10 or more, or may be 15 or more. The predetermined number of proximity measurement cycles may be a value up to 256, a value up to 128, or may be a value up to 64.

The offset determining system may be programmable, and the predetermined period of time may be programmed by an operator.

The offset determining system may be programmable, and the number of measurements that are used to determine the average signal may be programmed by an operator.

The offset determining system may be configured to identify drift if the average signal is between a first upper boundary threshold and a second upper boundary threshold, and the output signal is below the second upper boundary threshold.

The offset determining system may be configured to identify drift if the output signal is greater than a release threshold and the average signal is less than a pick-up threshold.

The offset determining system may be configured to identify drift if the average signal is greater than a third upper boundary threshold and the output signal is less than a fourth upper boundary threshold.

The offset determining system may also be configured to identify drift if the average signal falls below a lower boundary threshold.

The offset determining system may also be configured to reset the measurement of the time when the offset is adjusted.

The detection system may comprise a first amplifier stage configured to amplify an output from the detector and provide an intermediate output, and a second amplifier stage configured to receive the intermediate output and the offset and to provide an output signal.

According to a third aspect of the invention there is provided a smartphone or tablet comprising a body, a display screen a memory and a processor, and further comprising the proximity sensing system of the second aspect of the invention.

According to a fourth aspect of the invention there is provided a computer program comprising computer readable instructions configured to cause a computer to carry out a method according to the first aspect of the invention.

According to a fifth aspect of the invention there is provided a computer readable medium carrying a computer program according to the fourth aspect of the invention. Features of different aspects of the disclosure may be combined together.

Thus, embodiments of this disclosure advantageously allows drift to be identified but avoid movement of the system towards or away from an object being incorrectly identified as drift.

Finally, the proximity sensing method and system disclosed here utilise a novel approach at least in that drift is identified by comparing an output signal to a first threshold and comparing an average signal to a different threshold.

### BRIEF DESCRIPTION OF THE DRAWINGS

Some embodiments of the disclosure will now be described by way of example only and with reference to the accompanying drawings, in which:

FIG. 1 schematically depicts in cross-section a smartphone which includes a proximity sensing system according to an embodiment of the disclosure;

FIG. 2 is a circuit diagram depicting a circuit which forms part of the proximity sensing system;

FIG. 3 is graph which depicts how thresholds are used by a proximity sensing system to identify whether a device is close to an object or not close to an object;

FIG. 4 is a graph which shows a proximity sensing method according to an embodiment of the disclosure;

FIG. 5 is a flow-chart which depicts the proximity sensing method of FIG. 4;

FIG. 6 is a graph which depicts a proximity sensing method according to an embodiment of the disclosure, with different conditions; and

FIG. 7 is a flow-chart which depicts the proximity sensing method of FIG. 6.

### DETAILED DESCRIPTION OF THE PREFERRED EMBODIMENTS

Generally speaking, the disclosure provides a method of proximity sensing in which drift is identified by comparing an output signal to a first threshold and comparing an average signal (e.g. a rolling average) to a different threshold.

Some examples of the solution are given in the accompanying Figures.

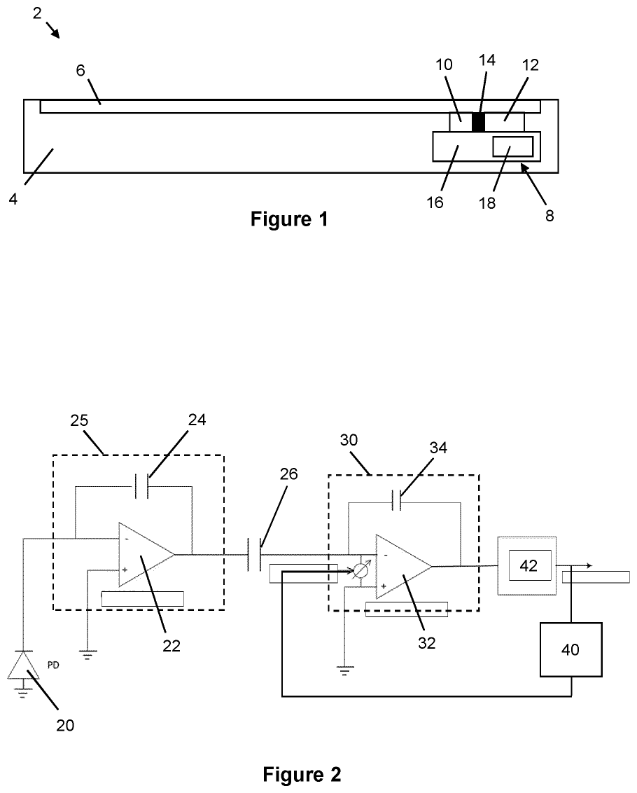

FIG. 1 is a schematic cross-sectional depiction of a smartphone 2. The smartphone comprises a housing 4 which holds a display 6. The display 6 may for example be an LED array (e.g. an OLED array) which may be used to display images and other matter to a user. A proximity sensing system 8 according to an embodiment of the disclosure is located beneath the display 6. In other embodiments the proximity sensing system 8 may be provided at a different location. Other components (not depicted) may also be provided in the smartphone. These may include a processor, memory, a cellular modem and an RF transceiver.

The proximity sensing system 8 comprises an emitter 10 and an optical detector 12. The emitter 10 may for example be a light emitting diode (LED), or a laser (e.g. a vertical cavity surface emitting laser, referred to as a VCSEL). The emitter may be configured to emit infra-red light. This is advantageous compared with visible light because it is not visible to a user. The optical detector 12 may for example be a photodiode (although other optical detectors may be used). The optical detector 12 may be referred to simply as a detector. A barrier 14, which is opaque to light emitted by the emitter 10 is located between the emitter and the optical detector 12. In some embodiments the barrier may be omitted.

The emitter 10, optical detector 12 and barrier 14 are all supported by a substrate 16. The substrate 16 may for example be a printed circuit board (PCB). Electronics 18 are connected to the emitter 10 and optical detector 12. The electronics 18 may control operation of the emitter 10 and the optical detector 12. The electronics receive an output signal from the optical detector 12 and use the signal to determine whether the smartphone 2 is close to an object. The electronics 18 are depicted as being located within the substrate 16. However, the electronics may be provided at any suitable location.

FIG. 2 is a circuit diagram which depicts part of electronics 18 of the proximity sensing system 8. A photodiode 20 (an example of the detector 12) is connected to a first amplifier stage 25. The first amplifier stage 25 comprises a first operational amplifier 22 with a capacitor 24 connected across the operational amplifier to an inverting input. The photodiode 20 is connected to the inverting input of the first operational amplifier 22. A non-inverting input of the operational amplifier 22 is connected to ground. An output of the first amplifier stage 25 is connected to a second capacitor 26.

In use, the emitter 10 (see FIG. 1) emits pulses of infrared light. When the smartphone 2 is adjacent to an object, the pulses are reflected from the object and are received by the photodiode 20 (which is an example of the optical detector 12 of FIG. 1). When a pulse of light is incident upon the photodiode 20, the photodiode provides an output charge. The size of the output charge is determined by the amount of infrared light incident upon the photodiode. The first amplifier stage 25 converts the output charge to an output voltage. When a second pulse of light is emitted by the emitter 10, reflected infrared light is again incident upon the photodiode 20. Charge output by the photodiode 20 is added to charge already output from the photodiode, and the output voltage from the first amplifier stage 25 increases accordingly. This occurs for a series of pulses from the emitter (e.g. eight pulses). The first amplifier stage 25 thus integrates current detected at the photodiode 20 and provides an output voltage at the second capacitor 26. Detection of reflected light for a series of pulses output from the emitter 10 may be referred to as a measurement cycle. An output voltage is provided at the second capacitor 26 for each measurement cycle.

A second amplifier stage 30 comprises a second operational amplifier 32 provided in parallel with a third capacitor 34. The third capacitor is connected across the second operational amplifier 32 to an inverting input. The second capacitor 26 is connected to the inverting input of the second operational amplifier 32. An output from an offset determining system 40 is connected across the inverting and non-inverting inputs of the second operational amplifier 32. This provides an offset to the second amplifier stage 30, as explained further below.

An output from the second operational amplifier stage 30 passes to an analog to digital converter (ADC) 42. The ADC 42 provides a digital output signal which indicates an offset adjusted intensity of infrared light detected by the photodiode 20. This output signal passes to a processor of the smartphone and passes to the offset determining system 40. The offset determining system 40 may be a programmable digital device.

The offset determining system may provide as an output an adjustment of the offset applied to the second operational amplifier 32. The processor of the smartphone may determine whether to switch off or on the display screen based upon the received output signal from the ADC.

The photodiode 20, first and second amplifier stages 25, 30, capacitor 26 and analogue to digital convertor 42 may be referred to as a detection system. Thus, the proximity sensing system may comprise the emitter, the detection system and the offset determining system 40.

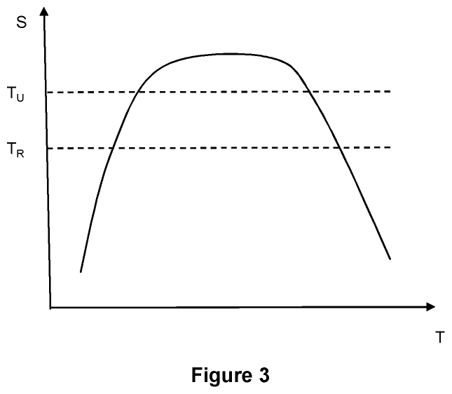

FIG. 3 is a graph which schematically depicts in simplified form how the output signal from the circuit of FIG. 2 may be used to determine an operational mode of the smartphone 2. In FIG. 3 the horizontal axis indicates time T and the vertical axis indicates the signal S output from the proximity sensing system 8.

Two thresholds are shown in FIG. 3. A first threshold T_{R} is used to determine when a user is moving the smartphone 2 away from their ear (or other object), and may be referred to as the release threshold T_{R}. A second threshold T_{U} is used to determine when a user moves the smartphone towards their ear (or other object), and may be referred to as a pick-up threshold T_{U}. An output signal from the proximity sensing system 8 is initially below both thresholds T_{R}, T_{U}. This means that infrared light emitted by the emitter 10 is not being reflected from a close object. Thus, normal operation of the smartphone is permitted, the display screen is switched on and touch-sensitivity is enabled.

A user picks up the smartphone 2 and moves it towards their ear. The output signal from the proximity sensing system 8 increases and crosses the release threshold TR. The release threshold is not used when a smartphone 2 is being moved towards an object. Therefore, crossing this threshold has no effect on operation of the smartphone. The output from the proximity sensing system 8 increases, indicating that the smartphone is being moved closer to the object. When the signal crosses the pick-up threshold T_{U} the smartphone 2 is determined to have moved close to the user's ear, and as a result the display screen is switched off and touch sensitivity is disabled.

The smartphone then stays close to the user's ear for a period of time, following which it is moved away from the object. The output signal from the proximity sensing system 8 decreases. The signal crosses the pick-up threshold T_{U}. Since the proximity sensing system is now monitoring for movement away from the object rather than movement towards the object, crossing this threshold has no effect. When the signal crosses below the release threshold T_{R} the smartphone is determined to have been moved away from the object. The screen is switched on and touch-sensitivity is enabled.

As explained further above, an offset is subtracted from the output of the first amplifier stage 25. This offset subtraction is desirable because it can correct for reflection of some emitted infrared light by the display screen 6 of the smartphone 2 (or other part of a smartphone). The amount of emitted infrared light which is reflected from the display screen 6 (or other part of a smartphone) may be determined by a calibration measurement. The calibration measurement may be performed after production of the smartphone. The measured reflected light may then be used as the offset which is applied to the signal output from the first amplifier stage 25. However, the output from the photodiode 20 may drift. One factor which may cause drift may for example be an elevated temperature in the vicinity of the proximity sensing system 8, which may modify optical properties of reflective surfaces of the smartphone. The elevated temperature may for example arise because the emitter 10 may generate a significant amount of heat (e.g. if the emitter is a VCSEL). Embodiments of the disclosure provide some correction for this drift, as is explained below.

Embodiments of the disclosure monitor the output signal from the proximity sensing system 8 (which may be referred to as a raw signal), and monitor a rolling average signal of the output signal from the proximity sensing system (which may be referred to as a rolling average signal). The rolling average signal is an average over a predetermined period of time or over a predetermined number of measurement cycles of the proximity sensing system 8. By monitoring the rolling average signal, the proximity sensing system is able to determine drift and correct for that drift. By monitoring the output (raw) signal, the proximity sensing system is able to sense and react to movement of the smartphone quickly without misinterpreting the movement as drift.

When the smartphone 2 is not close to an object, the offset determining system 40 may monitor and adjust the offset using an algorithm which uses the following rules:

If the rolling average signal is below a lower boundary threshold for n consecutive cycles, reduce the offset (this moves the rolling average signal back towards the lower boundary threshold).

If the rolling average signal is between a first upper boundary threshold and a second upper boundary threshold, and the output signal is below the second upper boundary threshold, for n consecutive cycles, then increase the offset (this moves the rolling average signal towards the first upper boundary threshold).

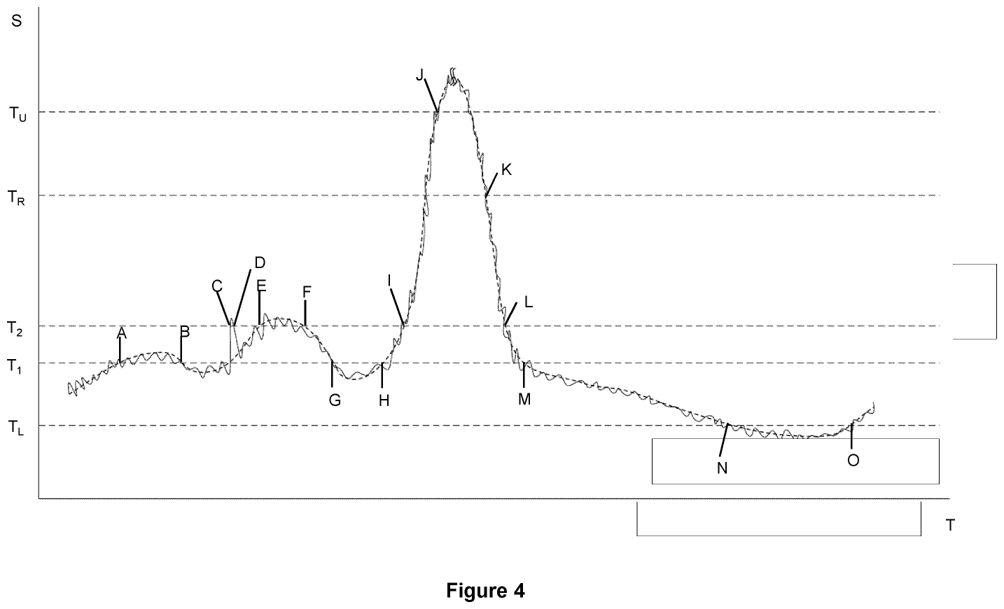

FIG. 4 is a graph which depicts operation of an embodiment of the disclosure using the above rules to adjust the offset applied to the output of the first amplifier stage 25. In FIG. 4 the horizontal axis is time and the vertical axis depicts both the output (raw) signal from the proximity sensing system 8 (depicted as a solid line) and a rolling average signal of the signal (depicted as a dashed line). The rolling average signal may be calculated by the offset determining system 40, and may be calculated using a predetermined number of output signal values. For example, 2 or more output signal values may be used. For example, up to 16 output signal values may be used. As is schematically depicted, the data includes some noise and thus fluctuates up and down. The rolling average signal averages out the noise. If a small number of output signal values (e.g. 2) are used to determine the rolling average then the rolling average may still be noisy. However, if a large number of output signal values (e.g. 16) are used to determine the rolling average, then identification of drift may be undesirably slow. A rolling average of at least 4 and less than 10 output measurements may provide a good balance between these requirements. As noted further above, each output signal value corresponds with a measurement cycle. A measurement cycle may take around 100 μs. Expressed in terms of time, the rolling average may use measurements taken over at least 200 μs, and may use measurements taken over up to 1.6 ms. The rolling average may use measurements taken over at least 400 μs, and may use measurements taken over less than 1 ms.

The rolling average signal may be calculated by the offset determining system 40, or may be calculated by other electronics.

In common with the graph depicted FIG. 3, in FIG. 4 a release threshold T_{R} and a pick-up threshold T_{U} are shown. However, three additional thresholds are now shown. The first of these is a lower boundary threshold T_{L}, the second is a first upper boundary threshold T₁ and the third is a second upper boundary threshold T₂. Embodiments of the disclosure seek to adjust the offset applied to the output signal such that when the smartphone is not close to an object the signal output from the proximity sensing system 8 is between the lower boundary threshold TL and the first upper boundary threshold T₁.

Embodiments of the invention also seek to determine when the smartphone comes close to an object, without interpreting the resulting change of output signal as being drift. This is achieved by using the output (raw) signal and the rolling average signal from the proximity sensing system 8.

Referring to FIG. 4, the smartphone is not close to an object at the point in time when the graph begins. The output from the proximity sensing system 8 is between the lower boundary threshold T_{L} and the first upper boundary threshold T₁. Thus, no drift is identified, and the offset is not changed.

Over time, the output from the proximity sensing system 8 increases. At point A the rolling average signal crosses the first upper boundary threshold T₁. Both the output signal and the rolling average signal are below the second upper boundary threshold T₂. The algorithm waits for four measurement cycles (n=4). The output signal remains below the second upper boundary threshold T₂ and the rolling average signal remains between the first and second upper boundary thresholds T₁, T₂ during those cycles. On this basis it is determined that the smartphone has not moved close to an object, but instead drift of the proximity sensing system 8 has occurred. The offset is increased. This moves the output signal and the rolling average signal towards the first upper boundary threshold T₁. The measurement cycle counter is reset (n=0). If the conditions remain satisfied after another four measurement cycles then the offset is increased again. In this case however, drift of the background signal is corrected after the first increase of the offset and no further adjustment of the offset is performed. The rolling average rolling average signal crosses the first upper boundary threshold T₁ (at point B). The conditions are no longer satisfied and so the=measurement cycle counter is reset (n=0).

At a later point in time C, the output signal increases rapidly and crosses both the first upper boundary threshold T₁ and the second upper boundary threshold T₂. The rolling average signal output crosses the first upper boundary threshold T₁ but does not at this time cross the second upper boundary threshold T₂. The rolling average signal output is between the first upper boundary threshold T₁ and the second upper boundary threshold T₂, as was the case at time A. However, the output signal is above the second upper boundary threshold T₂, and so the algorithm does not start incrementing the counter n.

At time D, the output crosses below the second upper boundary threshold T₂ (a peak of the output signal was caused by short-lived noise). Consequently, both the output signal and the rolling average signal are now between the first upper boundary threshold T₁ and the second upper boundary threshold T₂. The counter n starts to increment. If the conditions had remained satisfied for four measurement cycles then the background signal would have been determined to have drifted upwards, and the size of the offset applied to the background signal would have been increased. However, in this instance the conditions are not satisfied for four measurement cycles, and no adjustment is made to the offset.

Instead, at time E the rolling average signal output crosses the second upper boundary threshold T₂. The cycle counter n is reset (n=0). The algorithm continues to monitor to see if the conditions set out above are satisfied.

The output signal and the rolling average signal remain above the second upper boundary threshold T₂ for some time, during which no change of the offset is applied. The rolling average signal then crosses below the second upper boundary threshold T₂ at time F. The conditions required by the algorithm are now satisfied (the rolling average signal is between the first and second upper boundary thresholds T₁, T₂ and the output signal is below the second upper boundary threshold). The counter n begins to increment. In this instance the conditions do not hold true for four cycles, and instead the rolling output signal goes below the first upper boundary threshold T₁ at time G.

The counter n is reset (n=0). The output signal and the average output signal remain between the first upper boundary threshold T₁ and the lower boundary threshold TL. At time H, the average output signal crosses the first upper boundary threshold T₁. The output signal is below the second upper boundary threshold T₂. The counter n begins to count. However, the output signal crosses the second upper boundary threshold T₂ at time I before four cycles are completed. No adjustment of the offset is applied, and the counter is reset (n=0).

The output signal cross the release threshold T_{R}. The output signal then crosses the pick-up threshold T_{U} at time J. At this point the screen of the smartphone may be switched off and touch-sensitivity may be disabled (as discussed further above in connection with FIG. 3).

The signals then reduce, and pass first below the pick-up threshold T_{U} and then below the release threshold T_{R} at time K. When the signals pass below the release threshold T_{R} the smartphone screen may again be turned on and touch-sensitivity may again be enabled.

The rolling average signal passes below the second upper boundary threshold T₂ at time L. The rolling average signal is between the first and second upper boundary thresholds T₁, T₂ and the raw output is below the second upper boundary threshold. The counter n begins counting. The count does not reach four. Instead, at point M the rolling average signal cross below the first upper boundary threshold T₁. The counter n is reset (n=0). The algorithm continues to monitor the output signal and the rolling average signal.

The rolling average signal remains between the lower boundary threshold T_{L} and the first upper boundary threshold T₁. During this time the offset is not adjusted. The rolling average signal then passes below the lower boundary threshold T_{L} at time N. The counter n begins to count, and monitors to see whether the rolling average signal remains below the lower boundary threshold T_{L} for four cycles. This condition is satisfied, and is interpreted as meaning that drift has occurred. The offset is reduced, bringing the rolling average signal towards the lower boundary threshold T_{L} . The counter is reset (n=0). If the conditions remain satisfied after another four measurement cycles then the offset is reduced again. In this case however, drift of the background signal is corrected after the first reduction of the offset and no further adjustment of the offset is performed.

The rolling average signal crosses above the lower boundary threshold T_{L} at time O, rolling average rolling average signal crosses the first upper boundary threshold T₁ (at point B).

In the above described embodiment if the counter n counts four measurement cycles during which the conditions are satisfied then drift is identified. However, the counter may count a different number of measurement cycles. The number of measurement cycles may for example be a value up to 64, a value up to 128, or a value up to 256. A larger number of measurement cycles will reduce the likelihood that movement of the smartphone towards an object is incorrectly identified as drift. However, the larger number will reduce the rate at which drift is corrected. This could allow significant drift to occur before correction, although drift is generally slow and so a relatively large number may provide sufficiently good drift identification (e.g. 15 or more). In general, the number of measurement cycles may be 3 or more, for example 10 or more. The number of measurement cycles may for example be 128 or less. Expressed in terms of time, the algorithm may determine whether the conditions are satisfied for 300 μs or more, for example 1 ms or more. The algorithm may determine whether the conditions are satisfied for up to 26 ms. Other times, which correspond with the above counter values multiplied by 100 μs may be used. Similar considerations may be applied to other embodiments of the disclosure.

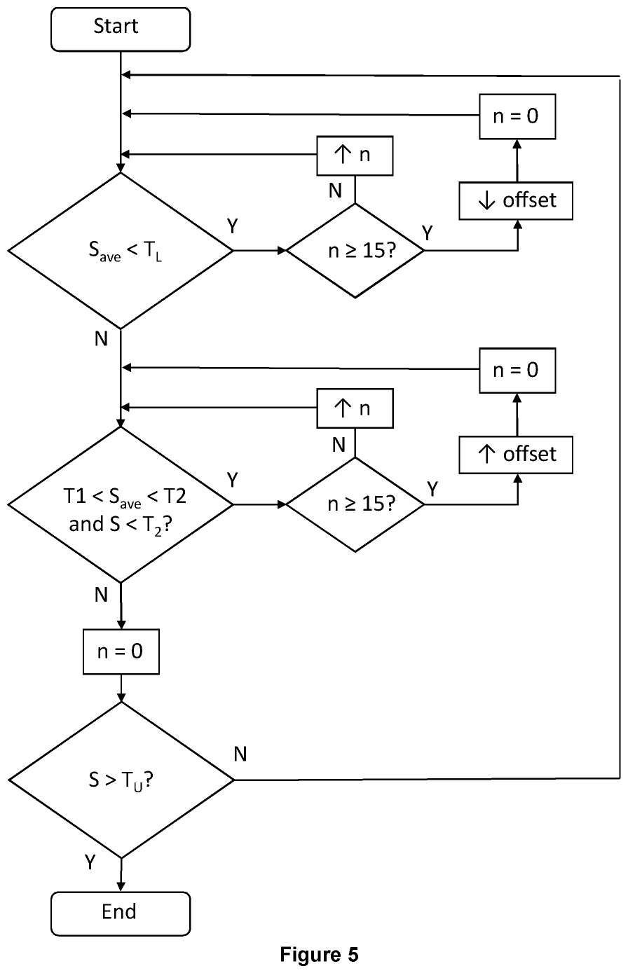

FIG. 5 is a flow chart which depicts the algorithm used by the embodiment of the disclosure. In the flowchart S is the output signal from the proximity sensing system 8, and Sₐᵥₑ is the average output signal from the proximity sensing system, n is the counter, T_{L} is the lower boundary threshold, T₁ is the first upper boundary threshold, T₂is the second upper boundary threshold, and Tᵤ is the pick-up threshold.

In FIG. 5, when the rolling average signal Save is below the lower boundary threshold T_{L}, a check is made to see if the counter value n is 15 or more. If the counter value is less than 15 then the counter is incremented and the next measurement cycle begins. If the counter value is 15 or more then the offset is reduced, the counter is reset and the next measurement cycle begins.

When the rolling average signal Sₐᵥₑ is not below the lower boundary threshold TL, the algorithm then checks the second set of conditions. These are is the rolling average signal Save between the upper and lower boundary thresholds T₁, T₂, and is the output signal S below the upper boundary threshold T₂? If both of these conditions are satisfied then a check is made to see if the counter value n is 15 or more. If the counter value is less than 15 then the counter is incremented and the next measurement cycle begins. If the counter value is 15 or more then the offset is increased, the counter is reset and the next measurement cycle begins.

If none of the conditions are satisfied then the counter n is set to zero. The algorithm determines whether the output signal is greater than the pick-up threshold Tᵤ. If the output signal is not greater than the pick-up threshold Tᵤ then the next measurement cycle begins. If the output signal greater than the pick-up threshold then pick-up of the smartphone is identified and the algorithm ends.

An embodiment of the disclosure may be used to correct for drift in different conditions, e.g. when the smartphone is close to an object (e.g. close to a user's ear). It is desirable to correct for such drift because in the absence of drift correction the output from the proximity sensor is more likely to saturate, and as a result switching on the screen of a smartphone and enabling touch-sensitivity may otherwise not occur correctly when the smartphone is moved away from the object.

When the smartphone 2 is close to an object, the offset determining system 40 may monitor and adjust the offset using an algorithm which uses the following rules:

If the output signal is greater than the release threshold and the rolling average signal is below the pick-up threshold for n consecutive cycles, reduce the offset to bring the rolling average signal back towards the pick-up threshold. If the rolling average signal is greater than a third upper boundary threshold and the output signal is less than a fourth upper boundary threshold, then increase the offset to bring the rolling average signal back towards the third upper boundary threshold.

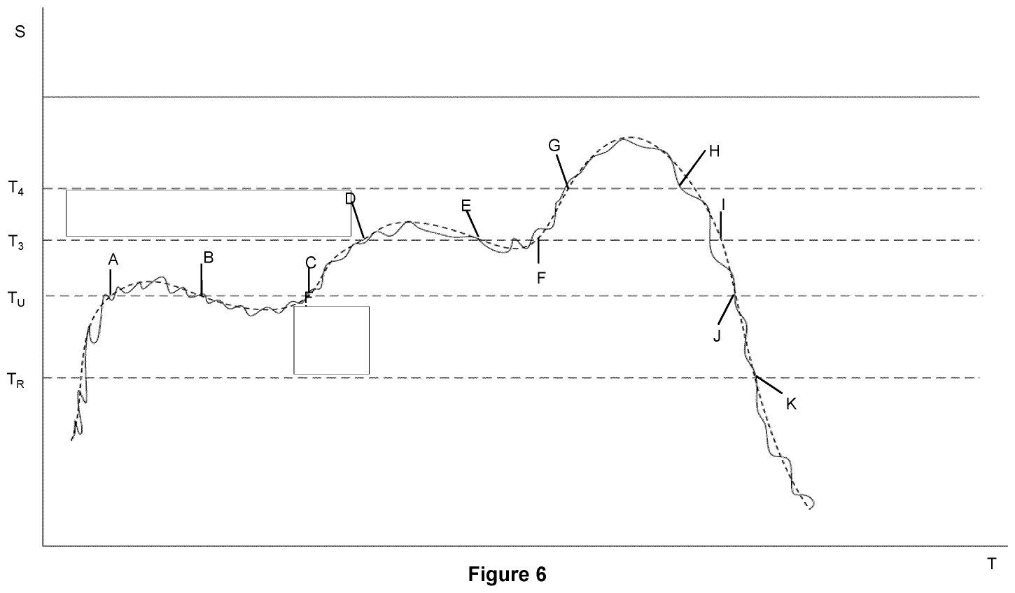

An example of operation using this algorithm is depicted in FIG. 6. Four thresholds are shown in FIG. 6. Two of the thresholds have already been described further above: these are the release threshold T_{R} and the pick-up threshold T_{U}. In addition a third upper boundary threshold T₃ and a fourth upper boundary threshold T₄ are also depicted. A solid line running across the top of FIG. 6 indicates saturation of the detector. In common with the algorithm described above in connection with FIGS. 4 and 5, the algorithm uses the output signal from the proximity sensing system 8 and the rolling average signal. This advantageously allows the algorithm to correct for drift but to also respond to movement of the smartphone away from the object without identifying that movement as drift.

In FIG. 6, as with FIG. 4, the output signal from the proximity sensing system 8 is depicted as a solid line and the rolling average signal is depicted as a dashed line.

Initially in FIG. 6 the smartphone is moving quickly towards an object (e.g. a user's ear). The output signal and the rolling average signal both cross the release threshold T_{R}, and then cross the pick-up threshold T_{U} at time A. When the rolling average signal crosses the pick-up threshold T_{U} the screen of the smartphone may be switched off and touch-sensitivity may be disabled.

The output signal and the rolling average signal are between the pick-up threshold T_{U} and the third upper boundary threshold T₃. As this is considered to be acceptable for the signals no adjustment of the offset is performed.

At time B the rolling average signal passes below the pick-up threshold T_{U}. The algorithm is monitoring for the combination of the rolling average signal being below the pick-up threshold T_{U} and the output signal being above the release threshold T_{R}. These conditions are satisfied and so a counter m starts incrementing. The counter reaches 4, at which point the offset is reduced. The counter is reset (m=0). If a further count is satisfied then a further reduction of the offset is applied. As depicted, the rolling average signal increases and crosses the pick-up threshold T_{U} at time C. The counter is reset (m=0).

At time D the rolling average signal output crosses above the third upper boundary threshold T₃. The algorithm is monitoring for the condition that the rolling average signal is above the third upper boundary threshold T₃ and the output signal is below the fourth upper boundary threshold T₄. This condition is satisfied at point D, and so the counter m begins incrementing. The algorithm monitors to see whether the conditions remain satisfied for 4 measurement cycles. In this instance the condition is satisfied for 4 measurement cycles, and consequently the offset is increased. The counter is reset (m=0). If further counts are satisfied then further increases of the offset are applied.

At point E in FIG. 5 the output signal and the rolling average signal cross below the third upper boundary threshold T₃. The counter m is reset (m=0).

At time F the rolling average signal again crosses above the third upper boundary threshold T₃. The algorithm again monitors to see if this condition remains true for 4 cycles. This is not the case because the output signal crosses the fourth upper boundary T₄ at time G. The counter is reset (m=0).

At time H the output signal crosses below the fourth upper boundary threshold T₄. The condition that the rolling average signal is above the third upper boundary threshold T₃ and the output is below the fourth upper boundary threshold T₄ is again satisfied. The counter m is incremented. In this instance the counter does not reach 4 and so no adjustment is applied to the offset. Instead the rolling average signal passes below the third upper boundary threshold at time I. The counter is reset (m=0).

At time J the rolling average signal output passes below the pick-up threshold T_{U}. The algorithm determines that the average is below the pick-up threshold T_{U} and the output signal is above the release threshold T_{R}. The counter is incremented. However, the number of increments does not reach 4. Instead, at time K the output signal passes below the release threshold T_{R}. At this time the display screen of the smartphone may be switched on and touch-sensitivity may be enabled.

The algorithm advantageously reduces the chance of the output from the proximity sensing system 8 saturating due to drift when the smartphone is close to an object. However, it is desirable to avoid that the offset becomes too large when the smartphone is close to an object, because if this is the case then the proximity sensor may not function correctly after the smartphone has moved away from the object (e.g. the method described above in connection with FIGS. 4 and 5 may start with an offset that is far too big). This is why further adjustments of the offset are not applied if the signal S exceeds the threshold T₄. Thus, the chance of saturation of the proximity sensing system output is reduced, but saturation is still allowed to occur when desirable.

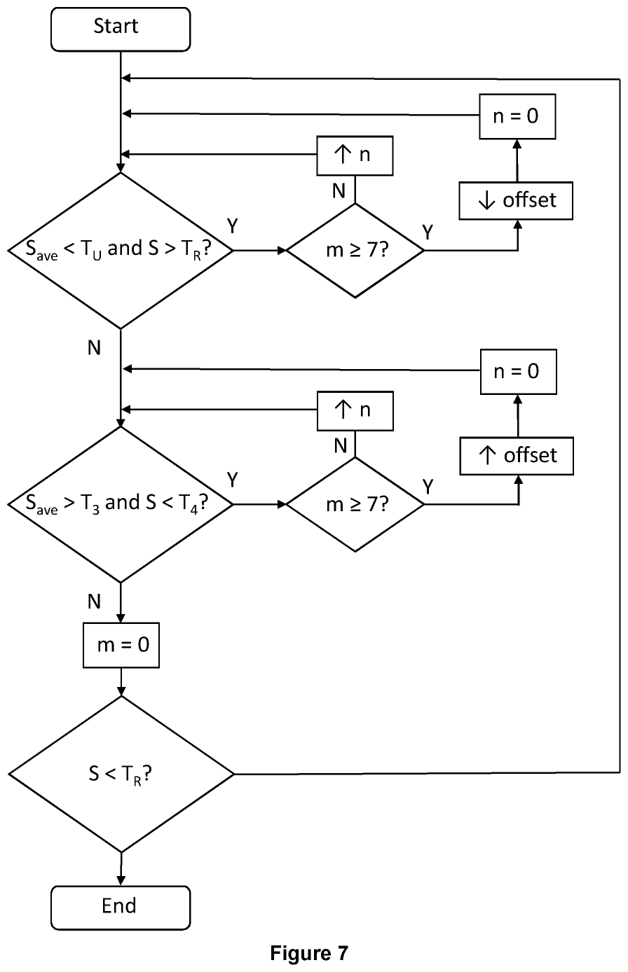

FIG. 7 is a flow chart which depicts the algorithm used by the embodiment of the disclosure when the smartphone is close to an object. In the flowchart S is the output signal from the proximity sensing system 8, Save is the average output signal from the proximity sensing system, m is the counter, T_{U} is the pick-up threshold, TD is the release threshold, T₃ is the third upper boundary threshold, and T₄ is the fourth upper boundary threshold.

The considerations set out above in connection with the counter n also apply in connection with the counter m. However, drift likely to occur more quickly when the smartphone is close to an object (a user may be on a telephone call and this may generate heat). Therefore, the counter value m may be less than the counter value n (or equivalently the measured elapsed time may be less when the smartphone is close to an object). In FIG. 7 the counter m value is 7. The counter value n may be 3 or more, may be 7 or more, or may be 15 or more. The counter value n may be a value up to 256, a value up to 128, or may be a value up to 64. Expressed in terms of time, the elapsed time may be 300 μs or more, may be 700 μs or more, or may be 1.5 ms or more. The time may be a value up to 26 ms, a value up to 13 ms, or may be a value up to 6 ms.

In general, values expressed as counts in this document may be converted into time periods by multiplying by 100 μs.

In FIG. 7, when the rolling average signal Sₐᵥₑ is below the pick-up threshold T_{L} and the output signal is above the release threshold T_{R}, a check is made to see if the counter value m is 7 or more. If the counter value is less than 7 then the counter is incremented and the next measurement cycle begins. If the counter value m is 7 or more then the offset is reduced. The counter is reset (m=0) and the next measurement cycle begins.

If the first set of conditions are not met, the algorithm checks the second set of conditions. These are is the rolling average signal above the third upper boundary threshold T₃ and is the output signal below the fourth upper boundary threshold T₄? If both of these conditions are satisfied then a check is made to see if the counter value m is 7 or more.

If the counter value is less than 7 then the counter is incremented and the next measurement cycle begins. If the counter value is 7 or more then the offset is increased. The counter is reset (m=0) and the next measurement cycle begins.

If none of the conditions are satisfied then the counter m is set to zero. The algorithm determines whether the output signal is below the release threshold T_{R}. If the output signal is below the release threshold T_{R} then release of the smartphone is identified and the algorithm ends. If the output signal is not below the release threshold T_{R} then the next measurement cycle begins.

As described above, the counting of measurement cycles is a convenient way of applying a time duration criterion to the algorithm. However, the time duration may be determined in other ways. For example, a predetermined number of clock cycles of the electronics may be used. In general, a predetermined period of time criterion may be applied for an embodiment where the smartphone is close to an object, and a predetermined period of time criterion may be applied for an embodiment where the smartphone is not close to an object. The predetermined periods of time may be the same or may be different (e.g. the predetermined period of time may be less when the smartphone is close to an object).

As mentioned further above, the emitter may emit a series of pulses (e.g. eight pulses) which are detected and are integrated by the proximity detection system to provide an output signal. This may be considered to be a measurement cycle. In other embodiments a measurement cycle may be defined differently. In other embodiments a measurement cycle may have a different number of pulses.

In general when criteria of the algorithm are satisfied, monitoring of the elapsed time begins, for example by counting the number of measurement cycles. When the criteria are no longer satisfied, or when the offset is adjusted, the monitoring of the time is reset. For example a counter of cycle times is reset.

Although the proximity sensing system has been described in a smartphone, in other embodiments the proximity sensing system may be in a tablet computer or other device.

In the above described embodiments the algorithm checks the conditions in a particular order. However, the conditions may be checked in any order. For example the order of the criteria in FIG. 5 may be reversed, or other changes may be made. The same applies for the criteria in FIG. 7.

The offset determining system 40 may comprise a memory and a processor. The offset determining system may be considered to be a computer. The offset determining system may be programmable. This may allow for example the number of counts m, n used by the method to be specified. It may also allow the number of measurement cycles that are used to calculate the rolling average signal to be programmed.

The output of the offset determining system 40 is an adjustment of the offset applied to the second amplifier 32. The adjustment does not seek to immediately return the rolling average signal to below a threshold (or above a threshold as appropriate). Instead, the adjustment moves the rolling average signal towards the threshold. Multiple adjustments may be applied to the rolling average signal until it is below the threshold (or above the threshold as appropriate). Making incremental adjustments of the offset in this manner advantageously avoids over-correction for drift.

In embodiments of the disclosure, if the rolling average signal crosses a threshold which may be indicative of drift, the output signal is determinative of whether drift is identified. This may advantageously ensure that movement of the proximity sensing system towards or from an object is not incorrectly identified as drift.

The described embodiment of the disclosure has a particular amplifier configuration. However, embodiments of the invention may be applied in a proximity sensing system with any amplifier configuration. Embodiments of the invention may be applied in a proximity sensing system with any configuration, provided that an output signal and an average signal are provided by the proximity sensing system.

When generating the rolling average, the number of measurement cycles used to determine the rolling average is preferably less than a count used to identify drift (e.g. the counts m and n of the embodiments).

Embodiments of the invention refer to a rolling average signal. However, other averages may be used. For example, a predetermined number of measurements may be obtained and an average determined, and then new measurements may be obtained (the same predetermined number of measurements, and used to determine a new average, etc. For example, four measurements may be used to determine an average, the next four measurements may be used to determine an average, etc. In general, an average signal may be used.

The skilled person will understand that in the preceding description and appended claims, positional terms such as ‘above’, ‘along’, ‘side’, etc. are made with reference to conceptual illustrations, such as those shown in the appended drawings. These terms are used for ease of reference but are not intended to be of limiting nature. These terms are therefore to be understood as referring to an object when in an orientation as shown in the accompanying drawings.

It will be appreciated that aspects of the present invention can be implemented in any convenient way including by way of suitable hardware and/or software. For example, a device arranged to implement the invention may be created using appropriate hardware components. Alternatively, a programmable device may be programmed to implement embodiments of the invention. The invention therefore also provides suitable computer programs for implementing aspects of the invention. Such computer programs can be carried on suitable carrier media including tangible carrier media (e.g. hard disks, CD ROMs and so on) and intangible carrier media such as communications signals.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in any embodiments, whether alone or in any appropriate combination with any other feature disclosed or illustrated herein.

1. A method of proximity sensing comprising:
emitting light from an emitter and detecting reflected light;
applying an offset to the detected reflected light to provide an output signal indicative of proximity;
determining an average signal of the output signal;
determining whether drift has occurred by comparing the output signal to a first threshold and comparing the average signal to a different threshold; and
adjusting the offset if drift is identified.

2. The method of claim 1, wherein drift is not identified until the output signal and the average signal satisfy the threshold criteria for drift for a predetermined period of time.

3. The method of claim 2, wherein the predetermined period of time is a predetermined number of proximity measurement cycles.

4. The method of claim 1, wherein drift is identified if the average signal is between a first upper boundary threshold and a second upper boundary threshold, and the output signal is below the second upper boundary threshold.

5. The method of claim 1, wherein drift is identified if the output signal is greater than a release threshold and the average signal is less than a pick-up threshold.

6. The method of claim 1, wherein drift is identified if the average signal is greater than a third upper boundary threshold and the output signal is less than a fourth upper boundary threshold.

7. The method of claim 1, wherein drift is also identified if the average signal falls below a lower boundary threshold.

8. The method of claim 2, wherein a measurement of the time is reset when the offset is adjusted.

9. A proximity sensing system comprising:
an emitter configured to emit light;
a detection system configured to detect reflected emitted light and provide an output signal indicative of proximity; and
an offset determining system configured to:
determine an average signal of the output signal;
determine whether drift has occurred by comparing the output signal to a first threshold and comparing the average signal to a different threshold; and
adjust the offset if drift of the offset is identified.

10. The system of claim 9, wherein the offset determining system is configured not to identify drift until the output signal and the average signal have satisfied the threshold criteria for drift for a predetermined period of time.

11. The system of claim 10, wherein the predetermined period of time is a predetermined number of proximity measurement cycles.

12. The system of claim 10, wherein the offset determining system is programmable, and the predetermined period of time may be programmed by an operator.

13. The system of claim 9, wherein the offset determining system is programmable, and the number of measurements that are used to determine the average signal may be programmed by an operator.

14. The system of claim 9, wherein the offset determining system is configured to identify drift if the average signal is between a first upper boundary threshold and a second upper boundary threshold, and the output signal is below the second upper boundary threshold.

15. The system of claim 9, wherein the offset determining system is configured to identify drift if the output signal is greater than a release threshold and the average signal is less than a pick-up threshold.

16. The system of claim 9, wherein the offset determining system is configured to identify drift if the average signal is greater than a third upper boundary threshold and the output signal is less than a fourth upper boundary threshold.

17. The system of clais 9, wherein the offset determining system is also configured to identify drift if the average signal falls below a lower boundary threshold.

18. The system of claim 9, wherein the offset determining system is also configured to reset the measurement of the time when the offset is adjusted.

19. The system of claim 9, wherein the detection system comprises a first amplifier stage configured to amplify an output from the detector and provide an intermediate output, and a second amplifier stage configured to receive the intermediate output and the offset and to provide an output signal.

20. A smartphone or tablet comprising a body, a display screen a memory and a processor, and further comprising the proximity sensing system of claim 9.

21. A computer program comprising computer readable instructions configured to cause a computer to carry out a method according to claim 1.

22. A computer readable medium carrying a computer program according to claim 21.
